(19) United States
(12) Patent Application Publication
(10) Pub. No.: US 2026/0355815 A1
(43) Pub. Date: Nov. 12, 2026

(54) SILVER SINTERING PASTE AND USE THEREOF FOR CONNECTING COMPONENTS

(71) Applicant: HERAEUS ELECTRONICS GMBH & CO. KG, Hanau (DE)

(72) Inventors: Ly May CHEW, Hanau (DE); Frank HERBERT, Hanau (DE); Michael SCHÄFER, Hanau (DE); Wolfgang SCHMITT, Hanau (DE)

(21) Appl. No.: 19/103,086

(22) PCT Filed: Jun. 19, 2023
(86) PCT No.: PCT/EP2023/066387

§ 371 Date: Feb. 11, 2025

(30) Foreign Application Priority Data
Aug. 17, 2022 (EP) 22190706.6

(51) Int. Cl. B22F 1/052; B22F 1/054; B22F 1/068; B22F 1/102; B22F 1/107; B22F 7/06

(52) U.S. Cl. CPC B22F 1/052; B22F 1/054; B22F 1/056; B22F 1/068; B22F 1/102; B22F 1/107; B22F 7/064; B22F 2301/255; B22F 2304/10; B22F 2304/15; B22F 2998/10; B22F 2999/00

(57) ABSTRACT

Silver sintering paste consisting of: (A) 5 to 40 wt. % of silver flakes with a particle size D90 in the range from 5 to 20 μm, (B) 50 to 85 wt. % of silver particles with a particle size D90 in the range from 300 to 1,000 nm, (C) 10 to 25 wt. % of at least one organic solvent, (D) 0 to 2 wt. % of at least one cellulose derivative, and (E) 0 to 10 wt. % of at least one additive different from constituents (A) to (D).

The present invention relates to a silver sintering paste and to a method for connecting components in which said silver sintering paste can be used.

The term “component” used herein refers in particular to component parts used in electronics, in short to electronic components. Examples of these include diodes, LEDs (light-emitting diodes), dies, IGBTs (insulated-gate bipolar transistors), MOSFETs (metal oxide semiconductor field effect transistors), ICs (integrated circuits), sensors, heat sinks, resistors, capacitors, coils, connecting elements (e.g., clips), base plates, antennas, lead frames, PCBs (printed circuit boards), flexible electronics, ceramic substrates, metal-ceramic substrates, such as DCB substrates (direct copper bonded substrates), IMS (insulated metal substrate), and the like.

The sintering connection of electronic components is common practice in the field of power and consumer electronics. Metal sintering pastes of which the main constituents are dispersed sinterable metal particles are frequently used as the connection material. Prominent examples of such sintering pastes include silver sintering pastes known to a person skilled in the art. The sintering connection technique represents a very simple method for the stable connection of components, wherein the components to be connected are transferred with their contact surfaces to be connected facing one another to a sandwich arrangement with sintering connection material, for example sintering paste, applied therebetween. The sandwich arrangement created using sintering paste is subsequently subjected to a drying and sintering step, in the course of which the mechanically strong, electrically and thermally conductive connection between the components is formed. The mechanically strong connection of two components is therefore a fastening of one component to or on the second component via the respective contact surfaces thereof.

The object of the invention was to provide a metal sintering paste that is improved in particular with regard to its squeeze-out behavior. The so-called squeeze-out behavior of a metal sintering paste is an undesired phenomenon of the metal sintering paste exiting, during the sintering process, from the edge region of a sandwich arrangement to be connected by sintering. This squeeze-out phenomenon can occur in particular in the case of so-called pressure sintering, and it can also occur increasingly if a relatively large quantity of metal sintering paste is located between components to be connected of a sandwich arrangement, i.e., if the layer thickness of the metal sintering paste is high and/or if the contact surfaces of relevant components to be connected to one another are large, for example such that the overlapping area formed by the contact surfaces to be connected is in the range of >100 mm², for example >100 to 500 mm² or more.

Surprisingly, the object can be achieved by providing a silver sintering paste consisting of:
(A) 5 to 40 wt. % (% by weight), preferably 10 to 30 wt. %, and particularly preferably 15 to 25 wt. %, of silver flakes (silver platelets) with a particle size D90 in the range from 5 to 20 μm, preferably 7 to 18 μm, and particularly preferably 8 to 15 μm,
(B) 50 to 85 wt. %, preferably 55 to 80 wt. %, and particularly preferably 60 to 75 wt. %, of silver particles with a particle size D90 in the range from 300 to 1,000 nm, preferably 320 to 800 nm, and particularly preferably 350 to 500 nm,
(C) 10 to 25 wt. %, preferably 10 to 20 wt. %, and particularly preferably 10 to 15 wt. %, of at least one organic solvent,
(D) 0 to 2 wt. %, preferably 0.1 to 1 wt. %, and particularly preferably 0.1 to 0.5 wt. %, of at least one cellulose derivative, and
(E) 0 to 10 wt. % of at least one additive different from constituents (A) to (D).

In a preferred embodiment, it is a silver sintering paste consisting of:
(A) 5 to 40 wt. %, preferably 10 to 30 wt. %, and particularly preferably 15 to 25 wt. %, silver flakes with a particle size D10 in the range from 0.5 to 2 μm, and preferably 0.7 to 1.5 μm, D50 in the range from 2.4 to 4 μm, and preferably 3 to 3.8 μm, and D90 in the range from 5 to 20 μm, preferably 7 to 18 μm, and particularly preferably 8 to 15 μm,
(B) 50 to 85 wt. %, preferably 55 to 80 wt. %, and particularly preferably 60 to 75 wt. %, of silver particles with a particle size D10 in the range from 90 to 150 nm, and preferably 100 to 120 nm, D50 in the range from 150 to 250 nm, and preferably 200 to 220 nm, and D90 in the range from 300 to 1,000 nm, preferably 320 to 800 nm, and particularly preferably 350 to 500 nm,
(C) 10 to 25 wt. %, preferably 10 to 20 wt. %, and particularly preferably 10 to 15 wt. %, of at least one organic solvent,
(D) 0 to 2 wt. %, preferably 0.1 to 1 wt. %, and particularly preferably 0.1 to 0.5 wt. %, of at least one cellulose derivative, and
(E) 0 to 10 wt. % of at least one additive different from constituents (A) to (D).

The terms, “particle size D10” or “particle size D90,” used herein in connection with the silver flakes (A) mean the primary particle diameter that can be determined by means of static automated analysis of microscopic images and that is undershot by a volume fraction of 10% of the particles or of 90% of the particles. The term, “particle size D50,” used herein in connection with the silver flakes (A) means the volume-average primary particle diameter that can be determined by means of static automated analysis of microscopic images. What is known as Equivalent Circular Area Diameter (ECAD) can expediently be used as a measure of the primary particle diameter (cf. RENLIANG XU ET AL: “Comparison of sizing small particles using different technologies,” POWDER TECHNOLOGY, ELSEVIER, BASEL (CH), vol. 132, no. 2-3, Jun. 24, 2003 (2003 Jun. 24), pages 145-153). The static automated analysis of the microscopic images can be carried out, for example, using the Morphologi 4 measuring system from Malvern Instruments according to the dry determination method.

The terms, “particle size D10” or “particle size D90,” used herein in connection with the silver particles (B) mean the primary particle diameter that can be determined by means of laser diffraction and that is undershot by a volume fraction of 10% of the particles or of 90% of the particles. The term, “particle size D50,” used herein in connection with the silver particles (B) means the volume-average primary particle diameter that can be determined by means of laser diffraction. What is known as Equivalent Circular Area Diameter (ECAD) can expediently be used as a measure of the primary particle diameter (cf. RENLIANG XU ET AL: “Comparison of sizing small particles using different technologies,” POWDER TECHNOLOGY, ELSEVIER, BASEL (CH), vol. 132, no. 2-3, Jun. 24, 2003 (2003 Jun. 24), pages 145-153). Laser diffraction measurements can be carried out using a corresponding particle size measuring instrument, for example a Mastersizer 3000 or Mastersizer 2000 from Malvern Instruments according to the wet determination method. In the wet determination method, for example, 1 g of silver particles of type (B) can be dispersed in 200 ml of ethanol by means of ultrasound as part of the sample preparation.

Constituent (A) is silver flakes with a particle size D90 in the range from 5 to 20 μm, preferably 7 to 18 μm, and particularly preferably 8 to 15 μm. The silver flakes preferably have a particle size D10 in the range from 0.5 to 2 μm, and preferably 0.7 to 1.5 μm, D50 in the range from 2.4 to 4 μm, and preferably 3 to 3.8 μm, and D90 in the range from 5 to 20 μm, preferably 7 to 18 μm, and particularly preferably 8 to 15 μm.

The aspect ratio of the silver flakes can, for example, be >5:1, for example, >5:1 to several hundred:1. The aspect ratio of particles describes the quotient of the largest and smallest linear expansions of the same and thus the shape thereof; only to avoid misunderstandings, in the case of particles in the form of flakes, the quotient of the largest and smallest linear expansions is the quotient of the largest length extension and the flake thickness. This can be determined using scanning electron microscopy and by evaluating the electron microscopic images by determining the dimensions of a statistically significant number of individual particles.

The silver flakes can have a specific surface area, for example, in the range from 1 to 5 m²/g. The specific surface area in m²/g can be determined by means of BET measurement according to DIN ISO 9277:2014-01 (static volumetric measurement method, gas used: nitrogen).

The silver flakes can have a tamped density, for example, in the range from 1 to 5 g/cm³. In comparison to the bulk density of a solid, the tamped density is the density further compressed by tamping or shaking. The tamped density in g/cm³ can be determined according to DIN EN ISO 787-11:1995-10.

The silver flakes are usually coated. The weight specifications given here include the weight of the coating on the silver flakes.

The silver flakes can comprise flakes of pure silver (purity of the silver of at least 99.9 wt. %) and/or of silver alloys with up to 10 wt. % of at least one other alloy metal. Examples of suitable alloy metals are copper, gold, nickel, palladium, platinum and aluminum. Silver flakes of pure silver are preferred.

The above-mentioned coating can be a firmly adhering layer on the surface of the silver flakes. Typically, this is an organic coating. The proportion of the organic coating can be, for example, in the range from 0.5 to 1.5 wt. %, based on silver or silver alloy. In general, such an organic coating can comprise 90 to 100 wt. % of one or more fatty acids and/or fatty acid derivatives. Examples of fatty acid derivatives include in particular fatty acid salts and fatty acid esters. Examples of fatty acids include caprylic acid (octanoic acid), capric acid (decanoic acid), lauric acid (dodecanoic acid), myristic acid (tetradecanoic acid), palmitic acid (hexadecanoic acid), margaric acid (heptadecanoic acid), stearic acid (octadecanoic acid), oleic acid (9-octadecenoic acid), arachidic acid (eicosanoic acid/icosanoic acid), behenic acid (docosanoic acid) and lignoceric acid (tetracosanoic acid).

In the case of a DSC analysis (differential scanning calorimetry, dynamic differential calorimetry) of the coated silver flakes carried out in the temperature range from, for example, 25 °C to 400 °C, with a heating rate of 10 K/min and air access, the coating of the silver flakes can be characterized, for example, by one or two exothermic peaks in the temperature range from, for example, 200 to 270 °C.

In the case of a TGA analysis (thermogravimetric analysis) of the coated silver flakes carried out in the temperature range from, for example, 25 °C to 400 °C with a heating rate of 10 K/min and air access, the coating of the silver flakes can be characterized, for example, by a weight loss in, for example, the range from 0.7 to 1.5 wt. %, beginning, for example, at 130 to 150 °C and ending, for example, at 220 to 240 °C.

Silver flakes of type (A) are available, for example, from Metalor or Ames Goldsmith.

Constituent (B) is silver particles with a particle size D90 in the range from 300 to 1,000 nm, preferably 320 to 800 nm, and particularly preferably 350 to 500 nm. Preferably, the silver particles have a particle size D10 in the range from 90 to 150 nm, and preferably 100 to 120 nm, D50 in the range from 150 to 250 nm, and preferably 200 to 220 nm, and D90 in the range from 300 to 1,000 nm, preferably 320 to 800 nm, and more preferably 350 to 500 nm. The silver particles of constituent (B) are so-called submicron silver particles, not to be confused with even smaller nano silver particles, which have D90 particle sizes of <250 nm.

The silver particles are not silver flakes; their aspect ratio is significantly smaller than that of silver flakes, for example in the range from 1:1 to 5:1. Ideal spherical particles have an aspect ratio of 1:1. The aspect ratio of the silver particles in the range from 1:1 to 5:1 means that the silver particles have, for example, a spherical, substantially spherical, elliptical, egg-shaped, or irregular shape, but in no case the shape of flakes.

The silver particles can comprise particles of pure silver (purity of the silver of at least 99.9 wt. %) and/or of silver alloys with up to 10 wt. % of at least one other alloy metal. Examples of suitable alloy metals are copper, gold, nickel, palladium, platinum and aluminum. Silver particles of pure silver are preferred.

The silver particles can have a specific surface area, for example, in the range from 1 to 8 m²/g. The specific surface area in m²/g can be determined by means of BET measurement according to DIN ISO 9277:2014-01 (static volumetric measurement method, gas used: nitrogen).

The silver particles can have a tamped density, for example in the range from 3 to 6 g/cm³. In comparison to the bulk density of a solid, the tamped density is the density further compressed by tamping or shaking. The tamped density in g/cm³ can be determined according to DIN EN ISO 787-11:1995-10.

The silver particles are usually coated. The weight specifications given here then include the weight of the coating on the silver particles.

The above-mentioned coating can be a firmly adhering layer on the surface of the silver particles. Typically, this is an organic coating. The proportion of the organic coating can be, for example, in the range from 0.5 to 1.5 wt. %, based on silver or silver alloy. In general, such an organic coating can comprise 90 to 100 wt. % of one or more fatty acids and/or fatty acid derivatives. Examples of fatty acid derivatives include in particular fatty acid salts and fatty acid esters. Examples of fatty acids include caprylic acid (octanoic acid), capric acid (decanoic acid), lauric acid (dodecanoic acid), myristic acid (tetradecanoic acid), palmitic acid (hexadecanoic acid), margaric acid (heptadecanoic acid), stearic acid (octadecanoic acid), oleic acid (9-octadecenoic acid), arachidic acid (eicosanoic acid/icosanoic acid), behenic acid (docosanoic acid) and lignoceric acid (tetracosanoic acid).

In the case of a DSC analysis of the coated silver particles carried out in the temperature range from, for example, 25 °C to 400 °C, with a heating rate of 10 K/min and air access, the coating of the silver particles can be characterized, for example, by one or two exothermic peaks in the temperature range from, for example, 200 to 270 °C.

In the case of a TGA analysis of the coated silver particles carried out in the temperature range from, for example, 25 °C to 400 °C with a heating rate of 10 K/min and air access, the coating of the silver particles can be characterized, for example, by a weight loss, for example, in the range from 0.9 to 1.4 wt. %, beginning, for example, at 140 to 160 °C and ending, for example, at 230 to 250 °C.

Silver particles of type (B) are available, for example, from Ames Goldsmith.

Constituent (C) is at least one organic solvent. Examples of suitable organic solvents include terpineols, N-methyl-2-pyrrolidone, ethylene glycol, dimethylacetamide, 1-tridecanol, 2-tridecanol, 3-tridecanol, 4-tridecanol, 5-tridecanol, 6-tridecanol, isotridecanol, 2-ethyl-1,3-hexanediol, 2-(2-ethylhexyloxy)-ethanol, benzyl alcohol, diethylene glycol monobutyl ether, dipropylene glycol monopropyl ether, dipropylene glycol monobutyl ether, dibasic esters (preferably dimethyl esters of glutaric, adipic or succinic acid or mixtures thereof), glycerol, diethylene glycol, triethylene glycol and aliphatic, in particular saturated aliphatic, hydrocarbons with 5 to 32 C atoms, more preferably 10 to 25 C atoms, and even more preferably 16 to 20 C atoms.

The optional constituent (D), which is preferably, however, comprised by the silver sintering paste according to the invention, is at least one cellulose derivative. Examples include methyl cellulose, ethyl cellulose, ethylmethyl cellulose, carboxycellulose, hydroxypropyl cellulose, hydroxyethyl cellulose, and hydroxymethyl cellulose.

The optional constituent (E) is at least one additive different from the constituents (A) to (D). Examples include surfactants, defoamers, wetting agents and anti-corrosion additives.

Constituent (E) preferably does not comprise any glass particles (glass frit); in other words, the silver sintering paste according to the invention preferably does not comprise any glass particles.

Constituent (E) particularly preferably comprises no thermally decomposable metal precursors (metal precursor compounds), i.e., no metal precursors that can be decomposed to the corresponding metal during the sintering process. Corresponding silver precursors sometimes customary in the silver sintering pastes of the prior art, such as silver oxide, silver carbonate, silver lactate, and the like, are thus, in particular, preferably not included in constituent (E). In other words, the silver sintering paste according to the invention particularly preferably comprises no thermally decomposable metal precursors. It has also been shown that the absence of such metal or silver precursors has a positive effect on the storage stability of a silver sintering paste according to the invention.

An essential invention characteristic of the silver sintering paste according to the invention appears to be that it has a combination of a relatively small proportion of silver flakes of type (A) with a relatively large proportion of submicron silver particles of type (B), and particularly preferably no proportions of the aforementioned metal or silver precursors.

The sum of the percentages by weight of constituents (A) to (E) is 100 wt. %, based on the silver sintering paste according to the invention. Accordingly, the production of a silver sintering paste according to the invention can take place by mixing the constituents (A) to (C) or (A) to (D), or (A) to (E). In this case, conventional devices known to a person skilled in the art can be used, for example stirrers, three-roll mills, guided jet mixers and/or dispersion mixers.

The silver sintering paste according to the invention can be used in a sintering method, for example in a sintering method as explained above. Sintering is understood to mean connecting two or more components by heating while preventing the silver flakes and the silver particles from reaching the liquid phase. The solid mechanical connection formed here is at the same time electrically and thermally conductive; it consists virtually or almost completely of silver. In this respect, the invention also relates to a method for connecting components, in which (1) a sandwich arrangement is provided which comprises at least two components and a silver sintering paste according to the invention located between the components, (2) the silver sintering paste is optionally, but preferably, dried, and (3) the sandwich arrangement is sintered. Drying is understood to mean the removal of organic solvent from the applied sintering paste according to the invention. When working with a silver sintering paste according to the invention, steps (1), (2), and (3) form a sequence of steps of type (1)-(2)-(3), with step (2) as an optional step. In one embodiment of the method carried out with the silver sintering paste according to the invention, step (1) can already comprise drying, and step (2) can thus be omitted; in another embodiment, step (1) does not comprise or only partially comprises drying, and optional step (2) can be omitted or, preferably, take place; if step (2) is omitted here, it can take place in the course of step (3) or can overlap said step.

The components can comprise at least one metal contact surface, for example in the form of a metallization layer, if they do not already consist of metal, via which at least one metal contact surface the aforementioned sandwich arrangement is made within the scope of the method according to the invention.

In step (1), the two or more components are first brought into contact with one another. The contacting takes place via the silver sintering paste according to the invention, which is optionally already dried. For this purpose, a sandwich arrangement is provided in which the silver sintering paste according to the invention is located in each case between two of the at least two components. The term “sandwich arrangement” means an arrangement in which two components are located one above the other and the components are arranged substantially in parallel with one another.

The sandwich arrangement can be produced according to a method known from the prior art. In this case, the relevant metal contact surface of one of the components is provided with the silver sintering paste according to the invention. Subsequently, the other component is placed with its metal contact surface onto the silver sintering paste which has been applied to the metal contact surface of the one component.

The application of the silver sintering paste according to the invention to the relevant metal contact surface of the one component can be carried out by means of conventional methods, for example by means of printing methods such as screen printing or stencil printing. On the other hand, the silver sintering paste according to the invention can also be applied by means of dispensing technology, jetting, by means of pin transfer, or by dipping.

The wet film thickness of the silver sintering paste according to the invention is preferably in the range from 20 to 400 μm. The preferred wet film thickness is, for example, dependent upon the selected application method. If the silver sintering paste according to the invention is applied, for example, by means of screen-printing methods, a wet film thickness of, for example, 20 to 60 μm may be preferred. If the application takes place, for example, by means of stencil printing, the preferred wet film thickness can be in the range from 20 to 400 μm, for example. For example, in the case of dispensing technology, the preferred wet film thickness can be, for example, in the range from 20 to 400 μm, depending on the application tool used, for example when using a hollow needle in the range from 20 to 100 μm or, for example, when using a wide-slot nozzle acting simultaneously as a doctor blade in the range from 50 to 400 μm.

Following the application of the silver sintering paste according to the invention to the metal contact surface of the one component, the metal contact surface of said component, which is provided with the silver sintering paste that is optionally already partially or completely dried, is brought into contact via the silver sintering paste with the corresponding metal contact surface of the component to be connected thereto. Thus, a layer of silver sintering paste according to the invention, which is not dried, partially dried, or completely dried, is located between the components to be connected with a view to forming the sandwich arrangement.

According to a preferred embodiment, the proportion of organic solvent in the silver sintering paste after drying is, for example, 0 to 5 wt. % based on the original proportion of organic solvent in the silver sintering paste according to the invention. In other words, during the drying according to this preferred embodiment, 95 to 100 wt. %, for example, of the organic solvent or of the organic solvents originally contained in the silver sintering paste according to the invention are removed.

The drying temperature in step (2), if carried out, is preferably in the range from 100 to 150 °C. Typical drying times are, for example, in the range from 5 to 45 minutes. To help shorten the drying time, a vacuum can be used, for example a pressure in the range from 100 to 300 mbar.

After the completion of step (1) or step (2), the sandwich arrangement is finally subjected to a sintering process. This sintering step (3) of the method according to the invention can be carried out under pressure or in an unpressurized manner. Carrying out the method in an unpressurized manner means that, despite the absence of mechanical pressure, a sufficiently firm connection can be achieved between components. As already stated at the outset, the silver sintering paste according to the invention is characterized by low or preferably even missing squeeze-out behavior; in other words, the silver sintering paste according to the invention has a particular suitability for the method according to the invention designed as pressure sintering.

The actual sintering takes place at a temperature of, for example, 200 to 280 °C and, as stated, either as an unpressurized process or, expediently, using the low-pronounced or non-present squeeze-out behavior as pressure sintering.

In the case of pressure sintering, the process pressure is preferably below 30 MPa and more preferably below 15 MPa. For example, the process pressure is in the range from 1 to 30 MPa and more preferably in the range from 5 to 15 MPa.

The sintering time is, for example, in the range from 2 to 90 minutes during pressure sintering, for example in the range from 2 to 5 minutes, and, for example, in the range from 30 to 75 minutes during unpressurized sintering.

The sintering process can take place in an atmosphere that is not subject to any particular restrictions. Thus, the sintering can be carried out on the one hand in an atmosphere containing oxygen. On the other hand, it is also possible to carry out the sintering in an oxygen-free atmosphere or in a vacuum. In the context of the invention, an oxygen-free atmosphere is understood to mean an atmosphere of which the oxygen content is no more than 300 ppm by weight, preferably no more than 100 ppm by weight and even more preferably no more than 50 ppm by weight.

The sintering is carried out in a conventional device suitable for sintering, in which the above-described process parameters can be set.

### EXAMPLES

### 1. Preparation of Silver Sintering Pastes:

The silver sintering pastes 1 to 5 according to the invention and the comparative pastes C1-C3 were prepared according to Table 1 (all specifications in wt. %). For this purpose, the organic solvents and, optionally, the ethyl cellulose were first homogenized at 80 °C to form a solvent system. Subsequently, the silver flakes and the silver particles were added to the solvent system in portions and completely dispersed.

### 2. Evaluation of the Silver Sintering Pastes:

### a) Preparation of Test Structures Serving as a Model:

The silver sintering pastes 1 to 5 according to the invention and the comparative pastes C1 to C3 were applied to a relevant silver-metallized copper-ceramic substrate with a wet film thickness of 300 μm by means of stencil printing. Directly thereafter, the respective regions of the printed silver sintering paste were provided with a further silver-metallized copper-ceramic substrate (20 mm×20 mm) over the entire area. The sandwich arrangements thus created were dried at a normal air atmosphere for 10 minutes at 120 °C. The subsequent pressure sintering was carried out under a nitrogen atmosphere (<100 ppm oxygen) in a hot press at 230 °C and 12 MPa for 5 minutes.

### b) Evaluation of the Squeeze-Out Behavior:

The sintered test structures were visually evaluated as to the extent to which an undesirable, squeezing-out of silver sintering paste at the edge took place.

If no sintering paste which was sintered and squeezed out at the edge under the contact surface of the loaded substrate during the sintering process was visible, the squeeze-out behavior was evaluated with “+” (no undesirable squeeze-out).

If sintered silver sintering paste on at least one edge of the test structure next to the loaded, silver-metallized, copper-ceramic substrate was visible on only <20% of the peripheral edge, the squeeze-out behavior was classified as “low.”

If sintered silver sintering paste on at least one edge of the test structure next to the loaded, silver-metallized, copper-ceramic substrate was visible on >50% of the peripheral edge, the squeeze-out behavior was classified as “high.”

### c) Determination of Shear Strength:

For the determination of the shear strength, the components were sheared off at 20 °C with a shear chisel at a speed of 2 mm/min. The force was recorded by means of a load cell of 10 kN (device from Zwick Roell Z010, Germany).

TABLE 1
Composition and evaluation of silver sintering pastes 1 to 5
according to the invention and comparative pastes C1 to C3

| | 1 | 2 | 3 | 4 | 5 | C1 | C2 | C3 |
|---|---|---|---|---|---|---|---|---|
| Silver flakes* | 7 | 10 | 12 | 17 | 30 | 52 | 84 | — |
| Silver | 80 | 77 | 75 | 70 | 57 | 35 | — | 87 |
| particles** | | | | | | | | |
| Ethyl cellulose | 0.1 | — | 0.1 | 0.1 | 0.1 | 0.1 | 0.3 | 0.1 |
| Terpineol | 6.45 | 6.50 | 6.45 | 6.45 | 6.45 | 6.45 | 7.85 | 6.45 |
| Diethylene | 6.45 | 6.50 | 6.45 | 6.45 | 6.45 | 6.45 | — | 6.45 |
| glycol | | | | | | | | |
| butyl ether | | | | | | | | |
| Dimethyl | — | — | — | — | — | — | 7.85 | — |
| succinate | | | | | | | | |

Evaluation:

| | | | | | | | | |
|---|---|---|---|---|---|---|---|---|
| Squeeze-out | low | + | + | + | + | + | + | high |
| behavior | | | | | | | | |
| Shear strength | 40 | 40 | 41 | 45 | 40 | 30 | 30 | 55 |
| (N/mm²) | | | | | | | | |

*Silver flakes coated with fatty acid: D90: 9 μm, D50: 3 μm, D10: 1 μm
**Silver particles coated with fatty acid: D90: 400 nm, D50: 200 nm, D10: 105 nm

1. Silver sintering paste consisting of
(A) 5 to 40 wt. % of silver flakes with a particle size D90 in the range from 5 to 20 μm,
(B) 50 to 85 wt. % of silver particles with a particle size D90 in the range from 300 to 1,000 nm,
(C) 10 to 25 wt. % of at least one organic solvent,
(D) 0 to 2 wt. % of at least one cellulose derivative, and
(E) 0 to 10 wt. % of at least one additive different from constituents (A) to (D).

2. The silver sintering paste according to claim 1 with a particle size D10 in the range from 0.5 to
2 μm and D50 in the range from 2.4 to 4 μm of the silver flakes and with a particle size D10 in the range from 90 to 150 nm and D50 in the range from 150 to 250 nm of the silver particles.

3. The silver sintering paste according to claim 1 with an aspect ratio of the silver flakes of >5:1.

4. The silver sintering paste according to claim 1 with a specific surface area of the silver flakes in the range from 1 to 5 m²/g.

5. The silver sintering paste according to claim 1 with a tamped density of the silver flakes in the range from 1 to 5 g/cm³.

6. The silver sintering paste according to claim 1 with an aspect ratio of the silver particles in the range from 1:1 to 5:1.

7. The silver sintering paste according to claim 1 with a specific surface area of the silver particles in the range from 1 to 8 m²/g.

8. The silver sintering paste according to claim 1 with a tamped density of the silver particles in the range from 3 to 6 g/cm³.

9. The silver sintering paste according to claim 1, wherein the at least one cellulose derivative is selected from the group consisting of methyl cellulose, ethyl cellulose, ethylmethyl cellulose, carboxycellulose, hydroxypropyl cellulose, hydroxyethyl cellulose, and hydroxymethyl cellulose.

10. The silver sintering paste according to claim 1, comprising no glass particles.

11. The silver sintering paste according to claim 1, comprising no thermally decomposable metal precursors.

12. A method for connecting components, in which (1) a sandwich arrangement is provided, which comprises at least two components and a silver sintering paste according to claim 1 located between the components, (2) the sintering paste is optionally dried, and (3) the sandwich arrangement is sintered.

13. The method according to claim 12, wherein sintering takes place under pressure or in an unpressurized manner.

14. The method according to claim 12, wherein the components are components used in electronics.
